(19) United States
(12) Patent Application Publication
(10) Pub. No.: US 2026/0333987 A1
(43) Pub. Date: Oct. 22, 2026

(54) DISPLAY DEVICE USING LIGHT-EMITTING ELEMENT, AND MANUFACTURING METHOD THEREFOR

(71) Applicant: LG ELECTRONICS INC., Seoul (KR)

(72) Inventors: Eunjeong KANG, Seoul (KR); Kyoungtae WI, Seoul (KR); Taehoon KIM, Seoul (KR); Yonghan LEE, Seoul (KR)

(73) Assignee: LG ELECTRONICS INC., Seoul (KR)

(21) Appl. No.: 19/109,507

(22) PCT Filed: Sep. 14, 2022
(86) PCT No.: PCT/KR2022/013674

§ 371 Date: Mar. 6, 2025

(51) Int. Cl. H10H 29/85; H10H 20/01; H10H 20/857; H10H 29/01; H10H 29/24; H10H 29/80; H10H 29/855

(52) U.S. Cl. CPC H10H 29/857; H10H 20/0364; H10H 20/857; H10H 29/034; H10H 29/0364; H10H 29/24; H10H 29/8421; H10H 29/8552

(57) ABSTRACT

The present disclosure is applicable to the technical field related to display devices, and relates to a display device using, for example, a micro light-emitting diode (LED), and a manufacturing method therefor. The present disclosure relates to a display device using a light-emitting element, comprising: a wiring substrate; an electrode pad which defines unit sub-pixel regions and which is arranged on the wiring substrate; a light-emitting element having a first type electrode arranged on the electrode pad; a connection unit including a plurality of conductive particles for electrically connecting the first type electrode of the light-emitting element to the electrode pad; a first paste layer located on the light-emitting element and the connection unit; and a second paste layer located on the first paste layer.

### TECHNICAL FIELD

The present disclosure is applicable to the technical field related to display devices, and for example, relates to a display device using a micro Light Emitting Diode (LED) and method for fabricating the same.

### BACKGROUND ART

Recently, in a field of a display technology, display devices having excellent characteristics such as thinness, flexibility, and the like are developed. On the other hand, currently commercialized major displays are represented by LCDs (liquid crystal displays) and OLEDs (organic light emitting diodes).

However, in the case of LCDs, there are problems, such as a non-fast response time and difficulty in implementing flexibility, and in the case of OLEDs, there are problems, such as a short lifespan and poor mass production yield.

On the other hand, light emitting diodes (LEDs) are semiconductor light emitting devices well known as converting current into light, and starting with commercialization of red LEDs using GaAsP compound semiconductors in 1962, they are used as light sources for display images in electronic devices including information and communication devices along with GaP: N-based green LEDs. Therefore, a solution to solve the above-described problems may be proposed by implementing displays using semiconductor light emitting devices. The semiconductor light emitting devices have various advantages, such as a long lifespan, low power consumption, excellent initial driving characteristics, and high vibration resistance, compared to filament-based light emitting devices.

The size of these semiconductor light emitting devices has recently been reduced to several tens of micrometers. Therefore, if a display device is implemented using these small-scale sized semiconductor light emitting devices, a very large number of semiconductor light emitting devices must be assembled on a wiring substrate of the display device.

However, in a process of assembling these light emitting devices, there is a problem in that it is very difficult to precisely locate a large number of semiconductor light emitting devices at desired positions of the wiring substrate. This problem is becoming more severe as high-resolution displays become more common.

In this assembly process, the light emitting devices may be directly transferred to wiring electrodes or transferred using a donor substrate. At this time, conductive balls or a conductive film may be used between the electrodes of the light emitting devices and the wiring electrodes.

A problem in bonding using a conductive film (ACF) including conductive balls is that there is a probability of electrical connection of small element pads due to randomness of conductive ball positions.

When bonding using a polymer resin forming an adhesive that exists as a surface, pressure required for bonding is high due to the flow and resistance of the resin depending on a contact area.

To improve a bonding margin, a partial resin coating method through a conductive paste (ACP) (pattern formation through a printing method by mixing conductive balls with a liquid) is being attempted to solve the problem.

With this solution, a degree of freedom of bonding using the ACP is higher than a degree of freedom of bonding using the ACF, but there is a problem that the ACP is not applicable to small elements due to the randomness of the positions of the conductive balls.

Meanwhile, a method of selectively forming a pattern of conductive balls on the N and P electrodes of light emitting devices on a chip on wafer (COW) has been developed, and a method of utilizing a non-conductive paste (NCP) as a bonding fixing material (adhesive part) is being used.

However, this thermal bonding has a limited bondable area due to the flatness and pressure of a bonding head.

In addition, excessive pressure or weak pressure may be applied to a specific area depending on the flatness and horizontality of the bonding head.

When bonding using conductive balls, in a local area where weak bonding pressure is applied, contact by the conductive ball may be released due to a spring back phenomenon in which the conductive ball is returned to the original position thereof at the moment when the pressure is released after bonding.

On the other hand, if excessive pressure is applied, the conductive balls have a Pac-man shape to lose restoring force, and thereby, the restoring force may not occur and thus contact may be released.

Meanwhile, when connecting an electrode of a light emitting device and a wiring electrode, a reflow electrical connection method using heat treatment is used. However, as a display area increases, electrical connection between an individual micro-LED and a wiring substrate through thermal bonding is not easy due to problems in implementing bonding equipment (an increase in pressure proportional to the flatness and area of a head).

For example, there is a problem that it is difficult to apply a method of printing a solder to an electrode pad pattern of a micro-LED with a small size of 10 μm.

When fabricating the solder using electroplating or a deposition method, there are difficulties in electrical connection of micro-LEDs due to cost issues and limitations of surface materials for resolving surface wettability That is, during the solder reflow heat treatment process, spread of the solder may cause electrical shorts between the N and P electrode pads of the light emitting device.

Accordingly, a solution that can solve these problems is

### DISCLOSURE

### Technical Tasks

One technical task of the present disclosure is to provide a display device using a light emitting device and method for fabricating the same that enable electrical connection under eased bonding conditions between a light emitting device having a micro or millimeter size and a wiring electrode.

In addition, another technical task of the present disclosure is to provide a display device using a light emitting device and method for fabricating the same that enable stable bonding of the light emitting device in case of a presence of a deviation in the height (size) of the light emitting device

In addition, further technical task of the present disclosure is to provide a display device using a light emitting device and method for fabricating the same that enable stable bonding of the light emitting device when a gap between the light emitting devices is narrow.

### Technical Solutions

In one technical aspect of the present disclosure, provided is a display device using a light emitting device, the display device including a wiring substrate. an electrode pad defining a unit sub-pixel area and arranged on the wiring substrate, a light emitting device having a first type electrode disposed on the electrode pad, a connection part including a plurality of conductive particles for electrically connecting the first type electrode of the light emitting device and the electrode pad, a first paste layer positioned on the light emitting device and the connection part, and a second paste-layer positioned on the first paste layer.

At least one of the first paste layer and the second paste layer may be positioned in units of one pixel area.

A height of the first paste layer may be the same as a height of an upper surface of the light emitting device.

A maximum height of the first paste layer may correspond to a highest height in the light emitting devices.

The display device may further include a cover layer positioned on the second paste layer.

An interface between the first paste layer and the second paste layer may connect the light emitting device and a light emitting device neighboring the light emitting device.

The interface between the first paste layer and the second paste layer may have a hang structure between the neighboring light emitting devices.

A height of the hang structure may be greater than a height deviation of the neighboring light emitting devices.

A height of the hang structure may be equal to or greater than half of a height of the light emitting device.

The second paste layer may include at least one of a reflective particle and a black particle.

The second paste layer may be configured to prevent the light emitting device from being separated from the electrode pad.

In another technical aspect of the present disclosure, provided is a method of fabricating a display device using a light emitting device, the method including applying a first paste layer including conductive particles on a wiring substrate having an electrode pad arranged thereon, disposing the light emitting device on the electrode pad, applying a second paste layer on the first paste layer, and pressing the light emitting device to be electrically connected to the electrode pad.

The applying the first paste layer including the conductive particles may include transferring the conductive particles onto the electrode pad and applying the first paste layer onto the electrode pad having the conductive particles transferred thereonto.

The first paste layer and the second paste layer may have different curing speeds.

The pressing may include positioning a first bonding head on the second paste layer, positioning a second bonding head at a lower side of the wiring substrate, and pressing the first bonding head and the second bonding head in a direction toward each other.

The pressing may be performed while applying heat.

At least one of the first paste layer and the second paste layer may be applied in units of one pixel area.

A deviation of a height of the light emitting device may be 10 to 20 μm.

A distance between the electrode pad and an electrode pad neighboring the electrode pad may be 35 μm or less.

The second paste layer may be configured to prevent the light emitting device from being separated from the electrode pad due to elasticity of the conductive particles after the pressing.

### ADVANTAGEOUS EFFECTS

According to an embodiment of the present disclosure, the following effects are obtained.

First, according to an embodiment of the present disclosure, an electrical contact area is widened between a conductive nanoparticle and a conductive microparticle (conductive ball) and excessive pressing is prevented, thereby establishing an electrical connection under eased bonding conditions between a micro-or millimeter-sized light emitting device and a wiring electrode.

In addition, according to an embodiment of the present disclosure, stable bonding of a light emitting device may be achieved when there is a deviation in the height (size) of the light emitting device.

In addition, according to an embodiment of the present disclosure, stable bonding of a light emitting device may be achieved when a gap between the light emitting devices is narrow.

Furthermore, according to another embodiment of the present disclosure, there are additional technical effects not mentioned herein, which are understood by those skilled in the through the entire purpose of the specification and drawings.

### DESCRIPTION OF DRAWINGS

FIG. 1 is a cross-sectional diagram illustrating a unit pixel of a display device using a light emitting device according to an embodiment of the present disclosure.

FIG. 2 is a cross-sectional diagram illustrating a unit pixel of a display device using a light emitting device according to another embodiment of the present disclosure.

FIGS. 3 to 6 are cross-sectional schematic diagrams illustrating steps of fabricating a display device using a light emitting device according to an embodiment of the present disclosure.

FIG. 7 is a flowchart illustrating steps of fabricating a display device using a light emitting device according to an embodiment of the present disclosure.

FIG. 8 is a diagram illustrating an example of a light emitting device applicable to a display device using the light emitting device according to an embodiment of the present disclosure.

FIG. 9 is a photograph showing a cross section of a display device fabricated by a conventional fabricating process as a comparative example.

FIG. 10 is a photograph showing a cross section of a display device fabricated by an embodiment of the present disclosure.

FIG. 11 is a photograph showing a screen state of a display device according to a comparative example.

FIG. 12 is a photograph showing a screen state of a display device according to an embodiment of the present disclosure.

### BEST MODE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two drawings are also within the scope of the present disclosure.

In addition, when an element such as a layer, region or module is described as being “on” another element, it is to be understood that the element may be directly on the other element or there may be an intermediate element therebetween.

Semiconductor light emitting devices described herein conceptually include LEDs, micro-LEDs, etc., and such terms may be used interchangeably.

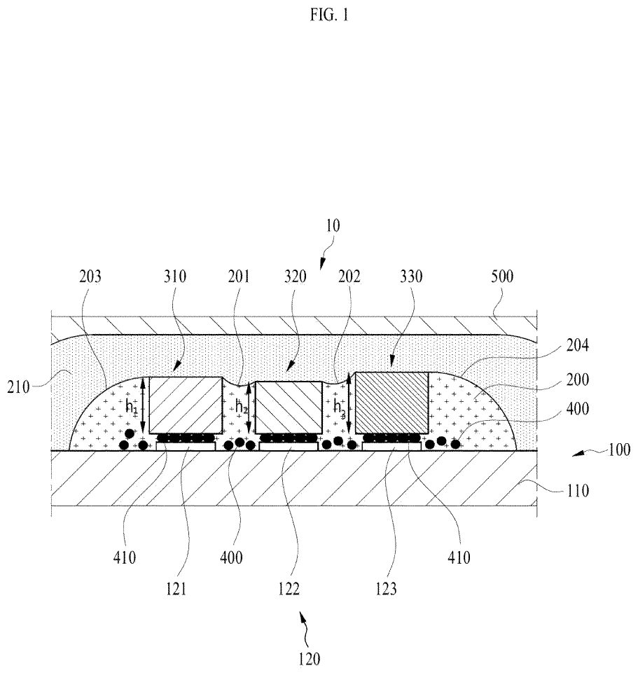

FIG. 1 is a cross-sectional diagram illustrating a unit pixel of a display device using a light emitting device according to an embodiment of the present disclosure.

Referring to FIG. 1, a display device 10 in which light emitting devices 310, 320, and 330 constituting a unit pixel are installed on a wiring substrate 100 is illustrated. For example, the light emitting devices 310, 320, and 330 constituting the unit pixel may include a first light emitting device 310, a second light emitting device 320, and a third light emitting device 330. For example, the first light emitting device 310 may be a red light emitting device 310 emitting red light, the second light emitting device 320 may be a green light emitting device 320 emitting green light, and also, the third light emitting device 330 may be a blue light emitting device 330 emitting blue light.

The wiring substrate 100 may be positioned on the substrate 110 in a manner that a plurality of wiring electrodes (not shown) are partitioned thereon. Here, the wiring electrode may include a data electrode (pixel electrode) and a scan electrode (common electrode).

Here, the three light emitting devices 310, 320, and 330 may form a unit pixel. These unit pixels may be repeatedly provided on the wiring board 100. In this case, one light emitting device may form a unit subpixel. FIG. 1 illustrates a state in which the light emitting devices 310, 320, and 330 are installed by being flip-chip-bonded.

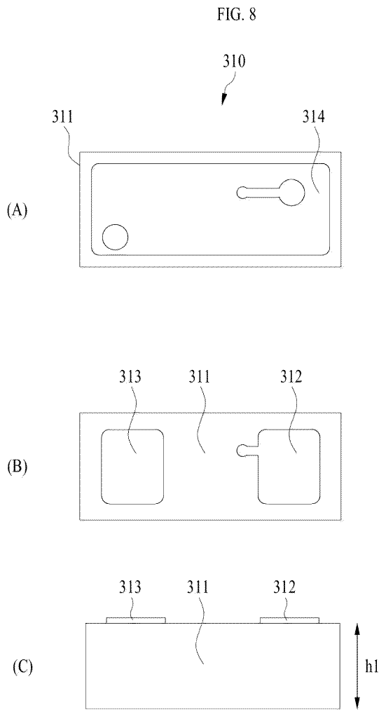

Electrode pads 120; 121, 122, and 123 connected to the wiring electrode may be positioned on the substrate 110. Here, shapes of the electrode pads 120; 121, 122, and 123 may be simplified and illustrated. Electrodes 312, 313 (see FIG. 8) of the light emitting devices 310, 320 and 330 may be electrically connected to the electrode pads 121, 122, and 123 by conductive particles 400 and 410. Also, a distance between the electrode pads 120; 121, 122, and 123 may be 35 μm or less. That is, the distance between the neighboring electrode pads 121, 122, and 123 may be 35 μm or less. As described above, when the distance between the neighboring electrode pads 121, 122, and 123 is 35 μm or less, electrical connection of the light emitting devices 310, 320 and 330 such as solder reflow may be unsuitable. In this case, a connection part 410 as described below and paste layers 200 and 210 having a multilayer structure covering the connection part 410 may be formed.

Here, the conductive particles 400 and 410 may have a size in micrometers (um). Therefore, the conductive particles 400 and 410 may be referred to as micro-conductive particles or conductive balls. The conductive particles 400 and 410 may form an electrical connection part between the electrode pads 121, 122, and 123 and the light emitting devices 310, 320, and 330. For example, the conductive particles 400 are applied between the electrode pads 121, 122, and 123 and the light emitting devices 310, 320, and 330 before forming a connection part, and then are deformed by a bonding process between the electrode pads 121, 122, and 123 and the light emitting devices 310, 320, and 330, thereby forming the connection part 410. That is, the conductive particles 400 may become conductive particles 410 deformed by the bonding process between the electrode pads 121, 122, and 123 and the light emitting devices 310, 320, and 330.

As described above, the light emitting devices 310, 320, and 330 in which at least one of the electrodes 312 and 313 (e.g., a first type electrode 312) is disposed may be disposed on the electrode pads 121, 122, and 123.

Although not shown, the electrode pad 120 arranged on the wiring board 100 may be connected to a TFT layer including a thin film transistor (TFT). A data electrode (pixel electrode) may be connected to the TFT layer. A detailed description thereof will be omitted.

As described above, a connection part including a plurality of conductive particles 410 electrically connecting the first type electrode 312 of the light emitting devices 310, 320, and 330 to the electrode pads 121, 122, and 123 may be provided. Hereinafter, the conductive particles 410 positioned between the electrode pads 121, 122, and 123 and the light emitting devices 310, 320 and 330 and the connection part 410 will be described using the same reference number.

Also, a first paste layer 200 may be positioned on the light emitting devices 310, 320, and 330 and the connection part 410. A second paste layer 210 may be positioned on the first paste layer 200.

As an exemplary embodiment, at least one of the first paste layer 200 and the second paste layer 210 may be positioned in one pixel area unit. That is, at least one of the first paste layer 200 and the second paste layer 210 may be positioned to cover the three light emitting devices 310, 320, and 330 constituting one pixel.

FIG. 1 illustrates an example in which the first paste layer 200 is positioned to cover the three light emitting devices 310, 320, and 330 forming one pixel and the second paste layer 210 is positioned on the first paste layer 200 forming such an area. However, depending on an embodiment, the first paste layer 200 may be positioned to cover a plurality of pixel areas. In addition, the second paste layer 210 may be positioned to cover a plurality of first paste layers 200 forming several areas.

As an exemplary embodiment, a height of the first paste layer 200 may be substantially the same as an upper surface of the light emitting devices 310, 320, and 330. Here, the meaning of “substantially” may mean that an acceptable error may be included in consideration of a process for an electrical connection (e.g., thermal compression) between the light emitting devices 310, 320, and 330 and the electrode pads 121, 122, and 123.

Also, as an example, a maximum height of the first paste layer 200 may correspond to the highest height among the light emitting devices 310, 320, and 330. In other words, the light emitting devices 310, 320, and 330 may have a height deviation, and the maximum height of the first paste layer 200 may correspond to a height of the light emitting device (in the case of FIG. 1, the third light emitting device 330) having the highest height among the light emitting devices 310, 320, and 330.

As described above, since the first paste layer 200 and the second paste layer 210 are formed of separate layers, an interface may be positioned between the first paste layer 200 and the second paste layer 210. That is, the first paste layer 200 and the second paste layer 210 may be distinguished from each other.

Furthermore, the interface between the first paste layer 200 and the second paste layer 210 may connect neighboring light emitting devices to each other. That is, the interface between the first paste layer 200 and the second paste layer 210 may be formed by connecting upper surfaces of the light emitting devices 310, 320, and 330 to each other.

Therefore, the interface between the first paste layer 200 and the second paste layer 210 may have a hang structure between the neighboring light emitting devices.

Referring to FIG. 1, a first interface 201 may be formed between the first light emitting device 310 and the second light emitting device 320. Also, a second interface 202 may be formed between the second light emitting device 320 and the third light emitting device 330. In this case, at least one of the first interface 201 and the second interface 202 may have a hang structure. That is, at least one of the first interface 201 and the second interface 202 may be formed to continuously connect upper surfaces of the neighboring light emitting devices to each other.

In addition, a height of the hang structure may be greater than a height deviation of the neighboring light emitting devices 310, 320, and 330.

Also, as an exemplary embodiment, the height of the hang structure may be at least half the height of the light emitting devices 310, 320, and 330.

As such, the first paste layer 200 may be formed by connecting the upper surfaces of the light emitting devices 310, 320, and 330 forming one pixel to each other. For example, a third interface 203 positioned outside the first light emitting device 310 may be formed by connecting an upper surface of the substrate 110 and the upper surface of the first light emitting device 310. Also, a fourth interface 204 positioned outside the third light emitting device 330 may be formed by connecting the upper surface of the substrate 110 and the upper surface of the third light emitting device 330.

As described above, the light emitting devices 310, 320, and 330 may have height deviations. Accordingly, a height of the third interface 203 and a height of the fourth interface 204 may be different from each other.

For example, the first light emitting device 310 may have a first height h1, the second light emitting device 320 may have a second height h2, and the third light emitting device 330 may have a third height h3. The deviation of the heights of the light emitting devices 310, 320, and 330 may be 10 to 20 μm.

The first paste layer 200 may stably protect the connection part 410 between the light emitting devices 310, 320, and 330 and the electrode pads 121, 122, and 123. Also, the first paste layer 200 may form a stable connection structure by binding the connection part 410 between the light emitting devices 310, 320, and 330 having the height deviations and the electrode pads 121, 122, and 123.

The second paste layer 210 may be for preventing the light emitting devices 310, 320, and 330 from being separated from the electrode pads during a bonding process between the light emitting devices 310, 320, and 330 and the electrode pads 121, 122, and 123. This will be described later in detail.

The first paste layer 200 and the second paste layer 210 may include different materials. For example, the first paste layer 200 and the second paste layer 210 may be formed of different materials, respectively. For example, the first paste layer 200 and the second paste layer 210 may be formed of materials having different curing speeds, respectively.

Referring to FIG. 1, a cover layer 500 may be positioned on the second paste layer 210. The cover layer 500 may protect the second paste layer 210. In some cases, the cover layer 500 may planarize the second paste layer 210. However, the cover layer 500 may be omitted. Also, a separate top cover may be positioned on the cover layer 500.

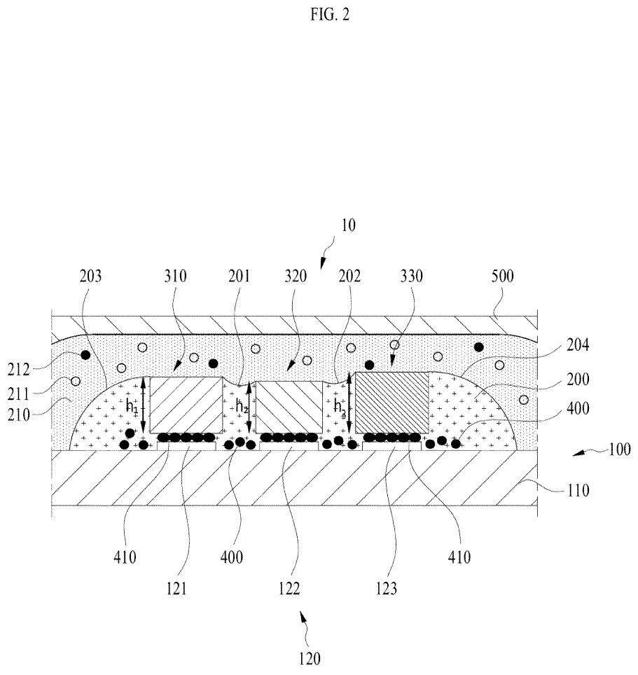

FIG. 2 is a cross-sectional diagram illustrating a unit pixel of a display device using a light emitting device according to another embodiment of the present disclosure.

Referring to FIG. 2, a display device 10 in which light emitting devices 310, 320, and 330 constituting a unit pixel are installed on a wiring board 100. For example, the light emitting devices 310, 320, and 330 constituting the unit pixel may include a first light emitting device 310, a second light emitting device 320, and a third light emitting device 330.

The wiring substrate 100 includes a substrate 110, and the electrode pads 121, 122, and 123 connected to the wiring electrode may be positioned on the substrate 110. Here, the shapes of the electrode pads 120; 121, 122, and 123 may be shown as simplified. Electrodes 312 and 313 (see FIG. 8) of the light emitting devices 310, 320 and 330 may be electrically connected to the electrode pads 121, 122, and 123 by conductive particles 400 and 410.

The conductive particles 400 and 410 may form electrical connections between the electrode pads 121, 122, and 123 and the light emitting devices 310, 320 and 330. The conductive particles 400 may include conductive particles 410 deformed by a bonding process between the electrode pads 121, 122, and 123 and the light emitting devices 310, 320 and 330.

Also, a first paste layer 200 may be positioned on the light emitting devices 310, 320, and 330 and the connection part 410. A second paste layer 210 may be positioned on the first paste layer 200.

Functional particles may be included in the second paste layer 210. For example, the second paste layer 210 may include reflective particles 211 through which light emitted from the light emitting devices 310, 320, and 330 may be reflected and emitted to the outside. As another example, black particles 212 capable of improving contrast may be included in the second paste layer 210. As such, at least one of the reflective particles 211 and the black particles 212 may be included in the second paste layer 210.

Besides, the present embodiment may be the same as the embodiment described above with reference to FIG. 1. Therefore, redundant descriptions are omitted.

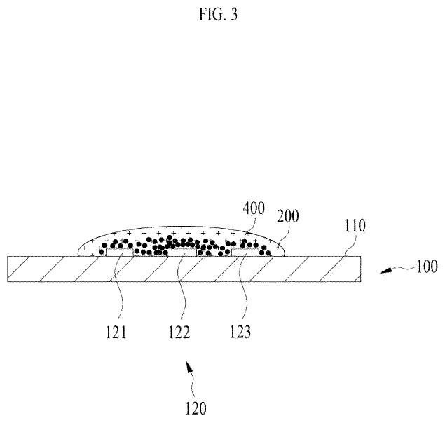

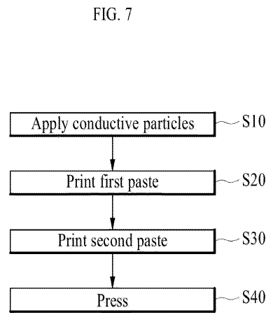

FIGS. 3 to 6 are cross-sectional schematic diagrams illustrating steps of fabricating a display device using a light emitting device according to an embodiment of the present disclosure. Also, FIG. 7 is a flowchart illustrating steps of fabricating a display device using a light emitting device according to an embodiment of the present disclosure.

Hereinafter, a process of fabricating a display device using a light emitting device according to an embodiment of the present disclosure will be described in detail with reference to FIGS. 3 to 6 together with FIG. 7.

First, referring to FIG. 3, a first paste layer 200 including conductive particles 400 may be applied on a wiring substrate 100 in which electrode pads 121, 122, 123 are arranged on one surface of a substrate 110 (S10, S20).

The conductive particles 400 may be evenly distributed in the first paste layer 200. Accordingly, a plurality of the conductive particles 400 may be positioned on the electrode pads 121, 122, and 123. Also, the conductive particles 400 may be positioned in portions other than the electrode pads 121, 122, and 123.

In this way, a step S10 of applying the conductive particles 400 and a step S20 of printing the first paste layer 200 may be performed simultaneously by printing the first paste layer 200 including the conductive particles 400.

However, depending on an embodiment, after the step S10 of applying the conductive particles 400 on the electrode pads 121, 122, and 123, the first paste layer 200 may be printed to cover the electrode pads 121, 122, and 123 to which the conductive particles 400 are applied (S20).

That is, as an exemplary embodiment, the step of applying the first paste layer 200 including the conductive particles 400 may include a step of transferring the conductive particles 400 on the electrode pads 121, 122, and 123, and a step of applying the first paste layer 200 on the electrode pads 121, 122, and 123 on which the conductive particles 400 are transferred.

In other words, an Anisotropic Conductive Paste (ACP), which is a liquid resin in which conductive particles 400 are dispersed, or an Immersive Conductive Paste (ICP) for coating a liquid resin after forming conductive balls only on an electrode may be printed on the electrode pads 121, 122, and 123 of the wiring board 100. In addition, depending on an embodiment, other materials that may be electrically connected to electrodes, in addition to the conductive particles 400, may be applicable.

As described above, at least three electrode pads 121, 122, and 123 may correspond to light emitting devices that define a single pixel.

Also, a distance between the electrode pads 120; 121, 122, and 123 may be 35 μm or less. That is, the distance between the neighboring electrode pads 121, 122, and 123 may be 35 μm or less. In this case, a connection part 410 for electrical connection of the light emitting devices 310, 320, and 330 and a structure of multi-layered paste layers 200 and 210 covering the connection part 410 may be formed.

Here, each of the conductive particles 400 and 410 may have a size in unit of micrometers (um). Therefore, the conductive particles 400 and 410 may be referred to as micro-conductive particles or conductive balls.

The first paste layer 200 may be positioned to cover at least three electrode pads 121, 122, and 123 corresponding to one pixel area. For example, the first paste layer 200 may be positioned to locally cover at least three electrode pads 121, 122, and 123 corresponding to one pixel area. However, depending on an embodiment, the first paste layer 200 may be positioned to cover a plurality of pixel areas.

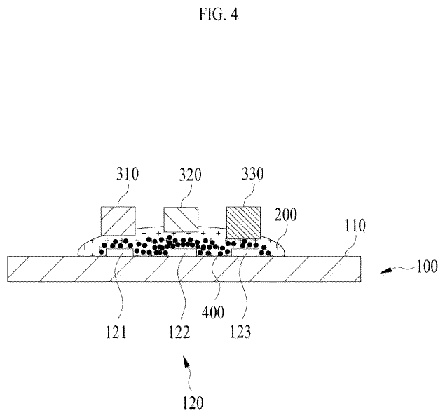

Next, referring to FIG. 4, light emitting devices 310, 320, and 330 may be positioned on the electrode pad 120. For example, the light emitting devices 310, 320, and 330 corresponding to the three electrode pads 121, 122, and 123 may be positioned.

As mentioned above, the light emitting devices 310, 320, and 330 may have height deviations. For example, the first light emitting device 310 may have a first height h1 (see FIG. 1), the second light emitting device 320 may have a second height h2 (see FIG. 1), and the third light emitting device 330 may have a third height h3 (see FIG. 1). The height deviations of the light emitting devices 310, 320, and 330 may be 10 to 20 μm.

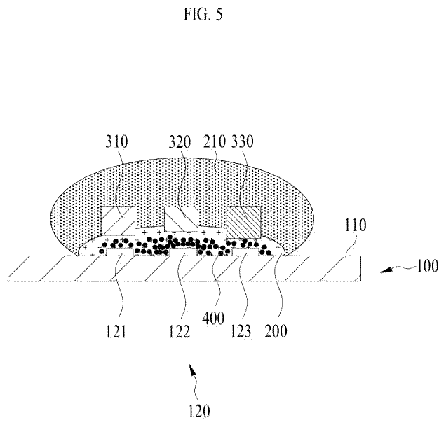

Thereafter, referring to FIG. 5, the second paste layer 210 may be applied (printed) to cover the light emitting devices 310, 320, and 330 (S30). The second paste layer 210 may be formed to cover the first paste layer 200 together with the light emitting devices 310, 320, and 330.

As shown in FIG. 5, the applied second paste layer 210 may have a thickness greater than that of the first paste layer 200.

As described above, the first paste layer 200 and the second paste layer 210 may have different physical properties. For example, the first paste layer 200 and the second paste layer 210 may have different physical properties such as viscosity, curing speed, hardness after curing, etc.

FIG. 5 illustrates an example in which the second paste layer 210 is positioned on the first paste layer 200 constituting one area. However, depending on an embodiment, the first paste layer 200 may be positioned to cover a plurality of pixel areas. In addition, the second paste layer 210 may be positioned to cover a plurality of the first paste layers 200 constituting several areas.

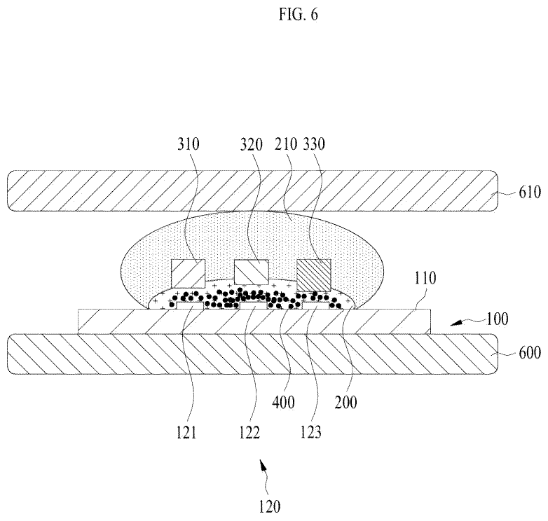

Next, referring to FIG. 6, a step S40 of pressing (bonding) the light emitting devices 310, 320, and 330 to be electrically connected to the electrode pads 121, 122, and 123 may be performed.

In the pressing step S40, a first bonding head 610 is positioned on the second paste layer 210 and the second bonding head 600 is positioned under the wiring substrate 100, so that the first bonding head 610 and the second bonding head 600 may be pressed in a direction in which they become closer to each other.

As an exemplary embodiment, the pressing step S40 may be performed while applying heat. That is, in the pressing step S40, the light emitting devices 310, 320, and 330 and the electrode pads 121, 122, and 123 may be pressed in a direction in which the light emitting devices 310, 320, and 330 and the electrode pads 121, 122, and 123 are brought close to each other while applying heat.

In this process, the light emitting devices 310, 320, and 330 may be prevented from being separated from the electrode pads 121, 122, and 123 due to the elasticity of the conductive particles 400 after the pressing step S40.

By the pressing step S40, the light emitting devices 310, 320, and 330 may be stably electrically connected (bonded) to the electrode pads 121, 122, and 123 by the conductive particles 410.

In this state, a cover layer 500 is formed on the second paste layer 210, so that a state as shown in FIG. 1 or FIG. 2 may be achieved.

Through this process, a plurality of the light emitting devices 310, 320, and 330 having thickness (height) deviations may be stably electrically connected (bonded) onto the electrode pads 121, 122, and 123.

That is, a plurality of the light emitting devices 310, 320, and 330 may be electrically connected onto the electrode pads 121, 122, and 123 despite the thickness (height) deviations.

The printing thickness of the first paste layer 200 may be smaller than the thickness of the light emitting devices 310, 320, and 330 in order to prevent the positional movement of the light emitting devices 310, 320, and 330 during the transferring process.

At least three light emitting devices 310, 320, and 330 constituting one RGB pixel may be mounted on a single print pattern in order to increase mass productivity. Accordingly, planarization of a portion where the light emitting devices 310, 320, and 330 are to be located in the print pattern may be required. However, when a pitch between the light emitting devices 310, 320, and 330 is narrowed or the sizes of the light emitting devices 310, 320, and 330 are miniaturized, there may be a limitation in forming a large pattern size itself.

Therefore, it is advantageous to mount the light emitting devices 310, 320, 330 that the printing thickness of the first paste layer 200 is smaller than the thickness of the light emitting devices 310, 320, and 330.

Therefore, in the embodiment of the present disclosure, stable electrical connection of the light emitting devices 310, 320, and 330 may be achieved by applying the second paste layer 210 capable of covering all step differences between the light emitting devices 310, 320, and 330 after applying the first paste layer 200 used for electrical connection.

FIG. 8 is a diagram illustrating an example of a light emitting device applicable to a display device using a light emitting device according to an embodiment of the present disclosure.

FIG. 8(A) shows a first surface of a light emitting device 310, and FIG. 8(B) shows a second surface of the light emitting device 310 where a first type electrode 312 and a second type electrode 313 are located.

The first type electrode 312 and the second type electrode 313 may be electrically connected to a semiconductor layer 311 of the light emitting device 310. Although not shown separately, the first type electrode 312 may be connected to a first type semiconductor (e.g., a p-type semiconductor), and the second type electrode 313 may be connected to a second type semiconductor (e.g., an n-type semiconductor).

Referring to FIG. 8(C), the red light emitting device 310 may have a first height h1. A growth substrate 314 may be positioned on the first surface of the light emitting device 310. Alternatively, a structure for light extraction may be positioned on the first surface.

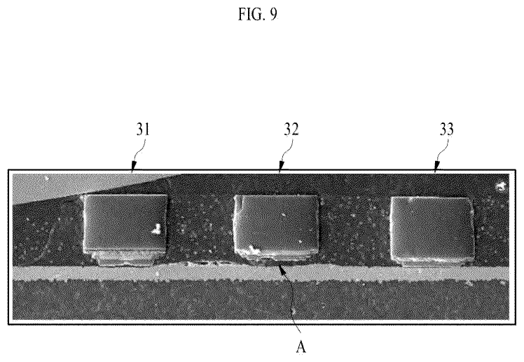

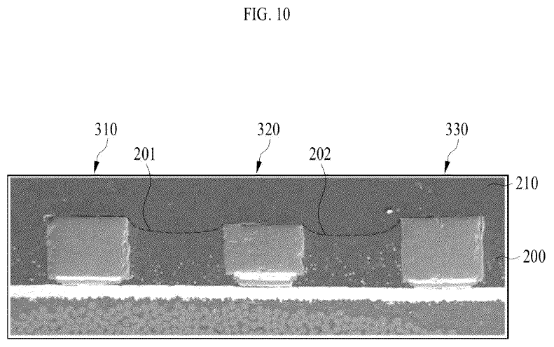

FIG. 9 is a photograph showing a cross section of a display device fabricated by a conventional fabricating process as a comparative example. Also, FIG. 10 is a photograph showing a cross section of a display device fabricated according to an embodiment of the present disclosure.

As an example, FIG. 9 shows a cross section of a display device including a single paste layer.

Referring to FIG. 9, there is a height deviation between light emitting devices 31, 32, and 33. In this case, it may be seen that in the case of the light emitting device 32 positioned at the center during a bonding process of the light emitting devices 31, 32, and 33, an electrode surface of a lower side of the light emitting device 32 and an electrode pad are not electrically connected and a gap A is generated therebetween.

The light emitting device 32 is not fixed on the electrode pad due to a height deviation during a pressing process, and a gap between the light emitting device 32 and the electrode pad is widened.

In other words, it may be seen that a contact of a local portion, to which weak bonding pressure is applied during bonding, by conductive balls is separated by a spring back effect in which the conductive balls tend to go back to their original positions as soon as the pressure is released after bonding.

On the other hand, referring to FIG. 10, it may be seen that light emitting devices 310, 320, and 330 having thickness deviations are stably bonded to electrode pads by the above-described structure and fabricating process.

Referring to FIG. 10, a first paste layer 200 including conductive particles and a second paste layer 210 for fixing the light emitting devices 310, 320, and 330 may be confirmed in cross-section.

In this case, it is possible to check a hanging phenomenon in which hang structures 201 and 202 are formed between the first light emitting device 310 and the second light emitting device 320 and between the second light emitting device 320 and the third light emitting device 330, respectively.

As a distance between the light emitting devices 310, 320, and 330 decreases, the difficulty of bonding increases, and an appropriate distance may be determined for visibility of a display module.

In the structure of the display device according to an embodiment of the present disclosure, the distance of each of the light emitting devices 310, 320, and 330 is about 1.2 times compared to the height of each of the light emitting devices 310, 320, and 330. This shows that bonding may be stably performed at a level of one time of the height-to-distance of the light emitting devices 310, 320, and 330 considering that the mounting precision (in the Pick and Place scheme) is ±15 μm.

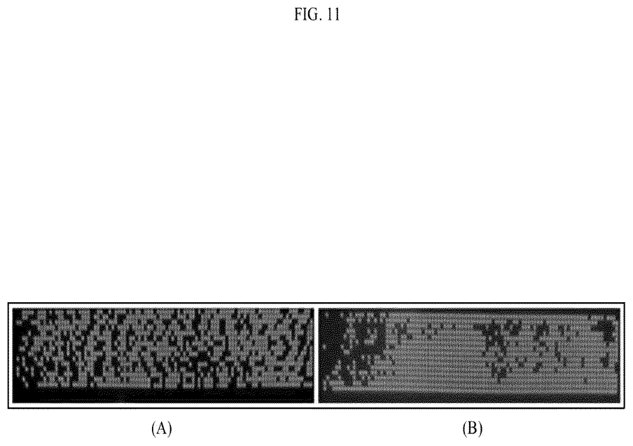

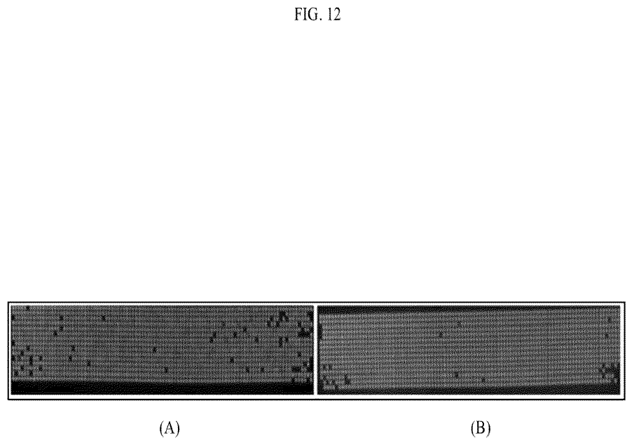

FIG. 11 is a photograph illustrating a screen state of a display device according to a comparative example. Also, FIG. 12 is a photograph illustrating a screen state of a display device according to an embodiment of the present disclosure.

In FIG. 11 and FIG. 12, a part of (A) shows that a green light emitting device 320 is turned on, and a part of (B) shows that a red light emitting device 310 is turned on.

When comparing FIG. 11 and FIG. 12, it may be seen that a rate of defective pixels in a display device according to an embodiment of the present disclosure is greatly reduced when light emission of a display is performed.

The above description is merely illustrative of the technical idea of the present disclosure. Those of ordinary skill in the art to which the present disclosure pertains will be able to make various modifications and variations without departing from the essential characteristics of the present disclosure.

Therefore, embodiments disclosed in the present disclosure are exemplary and not intended to limit the technical idea of the present disclosure, and the scope of the technical idea of the present disclosure is not limited by such embodiments.

The scope of protection of the present disclosure should be interpreted by the claims below, and all technical ideas within the scope equivalent thereto should be construed as being included in the scope of the present disclosure.

### INDUSTRIAL APPLICABILITY

According to the present disclosure, a display device using a semiconductor light emitting device such as a micro LED may be provided.

1. A display device using a light emitting device, the display device comprising:
a wiring substrate;
an electrode pad defining a unit sub-pixel area and arranged on the wiring substrate;
a light emitting device having a first type electrode disposed on the electrode pad;
a connection part including a plurality of conductive particles for electrically connecting the first type electrode of the light emitting device and the electrode pad;
a first paste layer positioned on the light emitting device and the connection part; and
a second paste layer positioned on the first paste layer.
wherein a height of the first paste layer is the same as a height of an upper surface of the light emitting device.

2. The display device of claim 1, wherein at least one of the first paste layer and the second paste layer is positioned in units of one pixel area.

3. (canceled)

4. The display device of claim 1, wherein a maximum height of the first paste layer corresponds to a highest height in the light emitting device.

5. The display device of claim 1, further comprising a cover layer positioned on the second paste layer.

6. The display device of claim 1, wherein an interface between the first paste layer and the second paste layer connects the light emitting device and a light emitting device neighboring the light emitting device.

7. The display device of claim 6, wherein the interface between the first paste layer and the second paste layer has a hang structure between the neighboring light emitting devices.

8. The display device of claim 6, wherein a height of the hang structure is greater than a height deviation of the neighboring light emitting devices.

9. The display device of claim 6, wherein a height of the hang structure is equal to or greater than half of a height of the light emitting device.

10. The display device of claim 1, wherein the second paste layer includes at least one of a reflective particle and a black particle.

11. The display device of claim 1, wherein the second paste layer is configured to prevent the light emitting device from being separated from the electrode pad.

12. A method of fabricating a display device using a light emitting device, the method comprising:
applying a first paste layer including conductive particles on a wiring substrate having an electrode pad arranged thereon;
disposing the light emitting device on the electrode pad;
applying a second paste layer on the first paste layer; and
pressing the light emitting device to be electrically connected to the electrode pad,
wherein a height of the first paste layer is the same as a height of an upper surface of the light emitting device.

13. The method of claim 12, wherein the applying the first paste layer including the conductive particles comprises:
transferring the conductive particles onto the electrode pad; and
applying the first paste layer onto the electrode pad having the conductive particles transferred thereunto.

14. The method of claim 12, wherein the first paste layer and the second paste layer have different curing speeds.

15. The method of claim 12, wherein the pressing comprises:
positioning a first bonding head on the second paste layer;
positioning a second bonding head at a lower side of the wiring substrate; and
pressing the first bonding head and the second bonding head in a direction toward each other.

16. The method of claim 12, wherein the pressing is performed while applying heat.

17. The method of claim 12, wherein at least one of the first paste layer and the second paste layer is applied in units of one pixel area.

18. The method of claim 12, wherein a deviation of a height of the light emitting device is 10 to 20 μm.

19. The method of claim 12, wherein a distance between the electrode pad and an electrode pad neighboring the electrode pad is 35 μm or less.

20. The method of claim 12, wherein the second paste layer is configured to prevent the light emitting device from being separated from the electrode pad due to elasticity of the conductive particles after the pressing.
